(19) United States
(12) Patent Application Publication
(10) Pub. No.: US 2023/0265562 A1
(43) Pub. Date: Aug. 24, 2023

(54) STABLE SILICON OXYNITRIDE LAYERS AND PROCESSES OF MAKING THEM

(71) Applicant: Applied Materials, Inc., Santa Clara, CA (US)

(72) Inventors: Fei Wu, San Jose, CA (US); Tae Kyung Won, San Jose, CA (US); Yu-Min Wang, Sunnyvale, CA (US); Young Dong Lee, San Jose, CA (US)

(73) Assignee: Applied Materials, Inc., Santa Clara, CA (US)

(21) Appl. No.: 17/677,106

(22) Filed: Feb. 22, 2022

(51) Int. Cl. C23C 16/513; C23C 16/30

(52) U.S. Cl. CPC C23C 16/513; C23C 16/308

(57) ABSTRACT

Exemplary methods of forming a silicon-oxygen-and-nitrogen-containing barrier layer are described. The methods include flowing deposition gases into a substrate processing region of a processing chamber, where the deposition gases include a silicon-containing gas and a nitrogen-containing gas. A deposition plasma is generated from the deposition gases in the substrate processing region. A silicon-oxygen-and-nitrogen-containing layer is deposited on a substrate from the deposition plasma, where the silicon-oxygen-and-nitrogen-containing layer is characterized by thickness of less than or about 2000 Å. The methods further include exposing a surface of the silicon-oxygen-and-nitrogen-containing layer to a treatment plasma to form a treated silicon-oxygen-and-nitrogen-containing layer, where the treatment plasma is formed from a nitrogen-containing gas and is silicon free.

### TECHNICAL FIELD

The present technology relates to deposition processes, structures, and systems. More specifically, the present technology relates to methods of producing stable silicon oxynitride layers.

### BACKGROUND

Integrated circuits are made possible by processes which produce intricately patterned material layers on substrate surfaces. Producing patterned material on a substrate requires controlled methods for forming and removing material. Material characteristics may affect how the device operates, and may also affect how the films are removed relative to one another. Plasma-enhanced deposition may produce films having certain characteristics. Many films that are formed require additional processing to adjust or enhance the material characteristics of the film in order to provide suitable properties.

Thus, there is a need for improved systems and methods that can be used to produce high quality devices and structures. These and other needs are addressed by the present technology.

### SUMMARY

Embodiments of the present technology include processing methods that include flowing deposition gases into a substrate processing region of a processing chamber. The deposition gases include a silicon-containing gas and a nitrogen-containing gas. The methods further include generating a deposition plasma from the deposition gases in the substrate processing region. The methods still further include depositing a silicon-oxygen-and-nitrogen-containing layer on a substrate from the deposition plasma. The methods yet further include exposing a surface of the silicon-oxygen-and-nitrogen-containing layer to a treatment plasma to form a treated silicon-oxygen-and-nitrogen-containing layer having a treated surface with an increased amount of silicon-nitrogen bonds and a decreased amount of silicon-oxygen bonds, wherein the treatment plasma is formed form a nitrogen-containing gas and is silicon free.

In additional embodiments, the silicon-oxygen-and-nitrogen-containing layer is characterized by thickness of less than or about 2000 Å. In further embodiments, the silicon-containing gas includes silane, and the nitrogen-containing gas includes nitrous oxide. In still further embodiments, the deposition gases further include ammonia. In yet additional embodiments, the deposition plasma is characterized by an ion density of greater than or about 1×10¹¹ ions/cm³, and the silicon-oxygen-and-nitrogen-containing layer deposition on the substrate is characterized by a deposition temperature of less than or about 100° C. In yet further embodiments, the treated silicon-oxygen-and-nitrogen-containing layer is characterized by a wet etch rate of less than or about 3000 Å/min. In more embodiments, the treated silicon-oxygen-and-nitrogen-containing layer is characterized by a density of greater than or about 2.1 g/cm³. In still more embodiments, the treated silicon-oxygen-and-nitrogen-containing layer is characterized by an index of refraction of less than or about 1.6.

Embodiments of the present technology further include additional processing methods that include depositing a first silicon-oxygen-and-nitrogen-containing layer on a substrate. The first silicon-oxygen-and-nitrogen-containing layer is characterized by a thickness of less than or about 500 Å. The methods further include depositing at least one additional silicon-oxygen-and-nitrogen-containing layer on the first silicon-oxygen-and-nitrogen-containing layer to form a multi-layer stack of silicon-oxygen-and-nitrogen-containing layers, wherein the multi-layer stack is characterized by a thickness of less than or about 2000 Å. The methods still further include exposing a top surface of the multi-layer stack to a treatment plasma to form a treated multi-layer stack. The treatment plasma is formed from a nitrogen-containing gas and is silicon free.

In additional embodiments, the first silicon-oxygen-and-nitrogen-containing layer and the at least one additional silicon-oxygen-and-nitrogen-containing layer are deposited with a deposition plasma characterized by an ion density of greater than or about 1×10¹¹ ions/cm³. In further embodiments, the deposition plasma is generated from deposition gases that include a silicon-containing gas and a nitrogen-containing gas. In still further embodiments, the treated multi-layer stack of silicon-oxygen-and-nitrogen-containing layers is characterized by an index of refraction of less than or about 1.6. In yet additional embodiments, the treated multi-layer stack of silicon-oxygen-and-nitrogen-containing layers is characterized by a wet etch rate of less than or about 3000 Å/min. In more embodiments, the nitrogen-containing gas in the treatment plasma includes ammonia.

Embodiments of the present technology still further include a structure that includes a substrate and at least one silicon-oxygen-and-nitrogen-containing layers. The silicon-oxygen-and-nitrogen-containing layers are characterized by a thickness of less than or about 2000 Å, a refractive index of less than or about 1.6, and a wet etch rate of less than or about 3000 Å/min.

In additional embodiments, the at least one silicon-oxygen-and-nitrogen-containing layers is a single layer. In further embodiments, the at least one silicon-oxygen-and-nitrogen-containing layers includes at least two layers of silicon-oxygen-and-nitrogen-containing materials, where each of the at least two layers is characterized by a thickness of less than or about 500 Å. In still further embodiments, the at least two layers of silicon-oxygen-and-nitrogen-containing materials include a top layer characterized by a stress level that is different than other layers of the silicon-oxygen-and-nitrogen-containing materials. In yet additional embodiments, the at least one silicon-oxygen-and-nitrogen-containing layer is characterized by a density of greater than or about 2.1 g/cm³. In more embodiments, the at least one silicon-oxygen-and-nitrogen-containing layer includes silicon oxynitride (SiON).

Such technology may provide numerous benefits over conventional processing methods to make silicon-oxygen-and-nitrogen-containing barrier layers. For example, barrier layers formed by the present processing methods are significantly thinner than conventional barrier layers having the same resistance to the migration of oxygen and moisture though the barrier layer. This permits the incorporation of thinner barrier layers into electronic products, such as electronic displays, with smaller device dimensions and increased device density. Among other benefits, the shrinking device dimensions made possible by the thinner barrier layers can produce higher resolution displays. In addition, the increased oxygen and moisture resistance of the present silicon-oxygen-and-nitrogen-containing barrier layers can increase the operational lifetime of the electronics products that incorporate the barrier layers. Because it takes significantly longer for oxygen and moisture to penetrate though the barrier layer and react with oxygen-and-moisture-sensitive materials in the underlying substrate, the electronics product can have a longer operational lifetime. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1A shows a top plan view of an exemplary processing system according to embodiments of the present technology.

FIG. 1B shows a schematic cross-sectional view of an exemplary plasma system according to embodiments of the present technology.

FIG. 2 shows operations of an exemplary method of processing according to embodiments of the present technology.

FIG. 3 shows an exemplary structure according to embodiments of the present technology.

FIG. 4 shows another exemplary structure according to embodiments of the present technology.

Several of the figures are included as schematics. It is to be understood that the FIGS. are for illustrative purposes, and are not to be considered of scale unless specifically stated to be of scale. Additionally, as schematics, the figures are provided to aid comprehension and may not include all aspects or information compared to realistic representations, and may include exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

An increasing number of electronic devices are made with greater amounts of moisture-sensitive materials. Electronic displays, for example, are increasingly made with organic light-emitting diodes (OLEDs) that include complex organic molecules that emit light in response to an electric current. These molecules can lose their light emitting characteristics when exposed to small amounts of moisture.

The development of protective barriers to block oxygen and moisture from reaching the moisture sensitive materials has played a prominent role in the wide adoption of moisture-sensitive electronic devices like OLED displays. These protective barriers include thin-film-encapsulation (TFE) barriers that cover the moisture-sensitive materials and prevent oxygen and moisture in the surrounding environment from reaching them. Examples of materials used to make TFE barriers include hydrophobic organic polymers and moisture-resistant inorganic materials. The effectiveness of these TFE barriers is evaluated on their ability to block oxygen and moisture, their resistance to cracking, and their ability to diffuse heat, among other characteristics.

One well-regarded material for TFE barriers is silicon oxynitride (SiON). SiON is relatively easy to deposit on moisture-sensitive materials using plasma-enhanced chemical vapor deposition processes. TFE barriers that include SiON provide good oxygen and moisture resistance under typical operating conditions for electronic devices, like OLED displays, over currently accepted lifetimes for these devices. However, the continued development of these devices is placing demands on TFE barriers to be more compact and have lower refractive indices without losing their effectiveness in blocking oxygen and moisture.

Embodiments of the present technology address the desire to make TFE barrier from SiON that are smaller than conventional SiON barrier layers. The present technology includes embodiments that deposit SiON-containing layers with the same as or greater resistance to oxygen and moisture penetration than conventional SiON layers that are twice as thick or more. The present technology also includes embodiments that deposit SiON-containing layers with refractive indices of less than or about 1.6 without reduced their effectiveness as moisture and oxygen barriers. In contrast, conventional SiON layers can experience significant degradation in their moisture and oxygen resistance when the RI falls below 1.63. In embodiments, the present SiON barrier layers may be characterized by a thickness of less or about 2000 Å and an RI less than or about 1.6, while conventional SiON barrier layers with comparable moisture resistance are characterized by thicknesses of greater than or about 5000 Å and an RI greater than or about 1.63.

Among other benefits, the present technology provides SiON-containing barrier layers with reduced thicknesses for moisture-sensitive electronic components and devices characterized by reduced size and increased complexity. Embodiments of the present technology decrease the thickness of an SiON barrier layer to less than half the thickness of a conventional SiON barrier layer, permitting a higher density of electronic components, such as OLED pixels, to occupy a given area. In additional embodiments, the SiON barriers are characterized by a refractive index of less than or about 1.6 without reducing their effectiveness as a barrier to moisture and oxygen. This permits the fabrication of more-compact, higher-resolution display devices without a reduction in operational lifetime due to moisture and oxygen degradation of moisture-sensitive materials in the devices.

Embodiments of the present technology include methods of forming and treating one or more silicon-oxygen-and-nitrogen-containing layers on a substrate. Embodiments further include the structures made by the methods. The description below starts with an embodiment of a system of the present technology upon which the present methods may be conducted. Although specific deposition and treatment processes utilizing the present technology are described, it will be readily understood that the systems and methods are equally applicable to other deposition and treatment systems, as well as processes as may occur in the described systems. Accordingly, the present technology should not be limited to the specific processes, structures, and systems described here. A system embodiment is first described, including a chamber used in the system to perform deposition and treatment processes according to embodiments of the present technology.

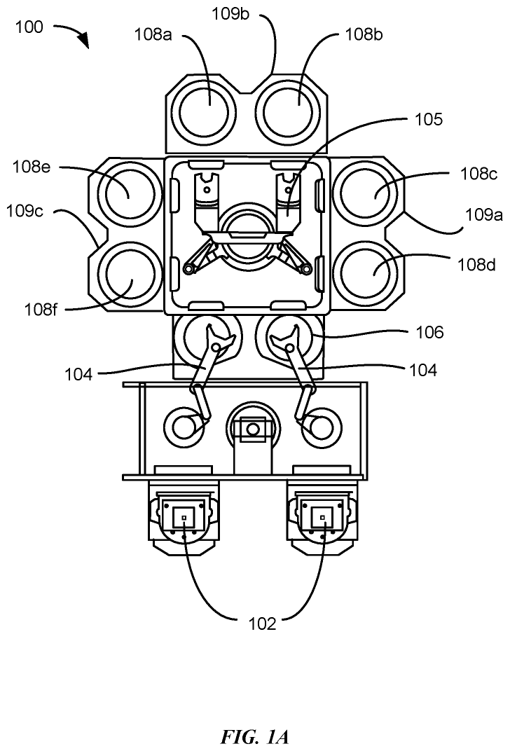

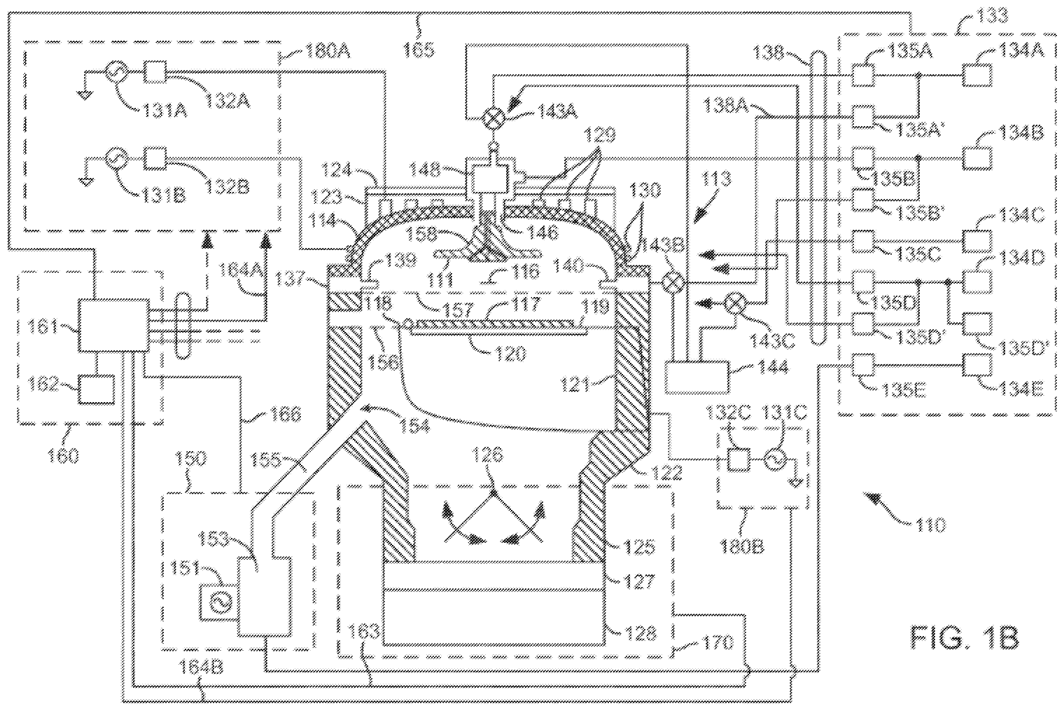

FIG. 1A shows a top plan view of an embodiment of a processing system 100 according to embodiments of the present technology. In embodiments, the processing system 100 may include deposition, treatment, etching, baking, and curing chambers, among other types of chambers. As shown in FIG. 1A, a pair of front opening unified pods 102 supply substrates of a variety of sizes that are received by robotic arms 104 and placed into a low pressure holding area 106 before being placed into one of the substrate processing chambers 108a-f, positioned in tandem sections 109a-c. A second robotic arm 105 may be used to transport the substrate wafers from the holding area 106 to the substrate processing chambers 108a-f and back. Each substrate processing chamber 108a-f, can be outfitted to perform one or more substrate processing operations, including the deposition and treatment of barrier layer materials as described herein. In embodiments, the substrate processing chambers 108a-f may be configured to perform plasma-enhanced chemical vapor deposition, atomic layer deposition, physical vapor deposition, etch, pre-clean, degas, orientation, and other substrate processes including, annealing, ashing, etc.

The substrate processing chambers 108a-f may include one or more system components for depositing, treating, annealing, curing and/or etching barrier layer materials on the substrate. In one configuration, two pairs of the processing chambers, e.g., 108c-d and 108e-f, may be used to deposit and treat barrier layer materials on the substrate, and the third pair of processing chambers, e.g., 108a-b, may be used to etch the deposited and treated barrier layer materials. In another configuration, all three pairs of chambers, e.g., 108a-f, may be configured to deposit a multi-layer stack of layers of barrier material on the substrate. Any one or more of the processes described may be carried out in chambers separated from the fabrication system shown in different embodiments. It will be appreciated that additional configurations of deposition, treating, etching, annealing, and curing chambers for barrier layer materials are contemplated by system 100.

FIG. 1B shows a schematic cross-sectional view of an exemplary plasma system 110 according to embodiments of the present technology. In the embodiment shown in FIG. 1B, the system 110 is an HDP-CVD system that includes a chamber 113, a vacuum system 170, a source plasma system 180A, a bias plasma system 180B, a gas delivery system 133, and a remote plasma cleaning system 150.

In embodiments, the upper portion of chamber 113 includes a dome 114, which may be made of a ceramic dielectric material, such as aluminum oxide or aluminum nitride, sapphire, SiC or quartz. among other materials. A heater plate 123 and a cold plate 124 may surmount and be thermally coupled to dome 114. Heater plate 123 and cold plate 124 may allow control of the dome temperature to within about ±10° C. over a range of greater than or about 70° C., greater than or about 80° C., greater than or about 90° C., greater than or about 100° C., greater than or about 110° C., or more. In embodiments, dome 114 may define an upper boundary of a plasma processing region 116. In further embodiments, plasma processing region 116 may be bounded on the bottom by the upper surface of a substrate 117 and a substrate support member 118.

In additional embodiments, the lower portion of chamber 113 may include a body member 122, which joins the chamber to the vacuum system. A base portion 121 of substrate support member 118 may be mounted on and form a continuous inner surface with, body member 122. Substrates may be transferred into and out of chamber 113 by a robot arm (not shown) through an insertion/removal opening (not shown) in the side of chamber 113. Lift pins (not shown) may be raised and then lowered under the control of a motor (also not shown) to move the substrate from the robot arm at an upper loading position 157 to a lower processing position 156 in which the substrate is placed on a substrate receiving portion 119 of substrate support member 118. Substrate receiving portion 119 may include an electrostatic chuck 120 that secures the substrate to support member 118 during substrate processing. In embodiments, substrate support member 118 may be made from an aluminum oxide or aluminum ceramic material.

In further embodiments, vacuum system 170 may include throttle body 125, which may house twin-blade throttle valve 126 and may be attached to gate valve 127 and turbo-molecular pump 128. It should be noted that throttle body 125 may offer minimum obstruction to gas flow and allow symmetric pumping. Gate valve 127 may also isolate pump 128 from throttle body 125 and can also control chamber pressure by restricting the exhaust flow capacity when throttle valve 126 is fully open. The arrangement of the throttle valve, gate valve, and turbo-molecular pump may be operable to provide accurate and stable control of chamber pressures from between about 1 millitorr to about 2 torr.

In still further embodiments, the source plasma system 180A may include a top coil 129 and side coil 130, mounted on dome 114. A symmetrical ground shield (not shown) reduces electrical coupling between the coils. Top coil 129 may be powered by top source RF (SRF) generator 131A, whereas side coil 130 may be powered by side SRF generator 131B, allowing independent power levels and frequencies of operation for each coil. This dual coil system may allow control of the radial ion density in chamber 113 to improve plasma uniformity. Side coil 130 and top coil 129 may be inductively driven, which does not require a complimentary electrode. In embodiments, the top source RF generator 131A may provide greater than or about 1,500 watts of RF power at nominally 13.56 MHz and the side source RF generator 131B may provide greater than or about 2,500 watts of RF power at nominally 13.56 MHz. The operating frequencies of the top and side RF generators may be offset from the nominal operating frequency (e.g., to 1.7-1.9 MHz and 1.9-2.1 MHz, respectively) to improve plasma-generation efficiency.

In more embodiments, a bias plasma system 180B may include a bias RF (“BRF”) generator 131C and a bias matching network 132C. The bias plasma system 180B may be capacitively coupled to the substrate portion 117 to body member 122, which act as complimentary electrodes. The bias plasma system 180B may serve to enhance the transport of plasma species (e.g., ions) created by the source plasma system 180A to the surface of the substrate. In embodiments, the bias RF generator may provide greater than or about 5,000 watts of RF power at 4 MHz.

In yet more embodiments, RF generators 131A and 131B may include digitally controlled synthesizers and operate over a frequency range between about 1.8 to about 2.1 MHz. Each generator may include an RF control circuit (not shown) that measures reflected power from the chamber and coil back to the generator and adjusts the frequency of operation to obtain the lowest reflected power. RF generators may be designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

In additional embodiments, matching networks 132A and 132B may match the output impedance of generators 131A and 131B with top coil 129 and side coil 130, respectively. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

In embodiments, the gas delivery system 133 may provide gases from several sources, 134A-134E chamber for processing the substrate via gas delivery lines 138 (only some of which are shown). As would be understood by a person of skill in the art, the actual sources used for sources 134A-134E and the actual connection of delivery lines 138 to chamber 113 varies depending on the deposition and cleaning processes executed within chamber 113. Gases may be introduced into chamber 113 through a gas ring 137 and/or a gas distributor 111. In embodiments, gas distributor 111 may include a first channel adapted to inject a silicon-containing gas, such as SiH₄, and a second channel adapted to inject one or more nitrogen-containing gases, such as N₂O and/or NH₃, which undergoes a chemical reaction with the source gas to form a silicon-oxygen-and-nitrogen containing material on the substrate. Work in relation with embodiments of the present invention suggests that such gas distributors can provide a uniform deposition of silicon-oxygen-and-nitrogen-containing material that avoids silicon rich deposition in the central region of the substrate, for example embodiments that use gas rings with nozzles distributed around the substrate near the side walls of the chamber.

In further embodiments, first and second gas sources, 134A and 134B, and first and second gas flow controllers, 135A′ and 135B′, may provide gas to ring plenum in gas ring 137 via gas delivery lines 138 (only some of which are shown). In more embodiments, gas ring 137 has a plurality of source gas nozzles 139 (only one of which is shown for purposes of illustration) that provide a uniform flow of gas over the substrate. Nozzle length and nozzle angle may be changed to allow tailoring of the uniformity profile and gas utilization efficiency for a particular process within an individual chamber. In embodiments, gas ring 137 may have twelve source gas nozzles made from an aluminum oxide ceramic. In further embodiments, source gas nozzles 139 inject a silicon-containing gas, such as SiH₄, into the chamber, which can be mixed with a nitrogen-containing gas, such nitrous oxide (N₂O), injected from additional nozzles to form the dielectric layer.

In yet further embodiments, gas ring 137 may also have a plurality of oxidizer gas nozzles 140 (only one of which is shown), which in a preferred embodiment are co-planar with and shorter than source gas nozzles 139, and in embodiments, receive gas from body plenum. In additional embodiments it may be desirable not to mix source gases and oxidizer gases before injecting the gases into chamber 113. In other embodiments, oxidizer gas and source gas may be mixed prior to injecting the gases into chamber 113 by providing apertures (not shown) between body plenum and gas ring plenum. In one embodiment, third, fourth, and fifth gas sources, 134C, 134D, and 134D′, and third and fourth gas flow controllers, 135C and 135D′, provide gas to body plenum via gas delivery lines 138. Additional valves, such as 143B (other valves not shown), may shut off gas from the flow controllers to the chamber.

In embodiments where flammable, toxic, or corrosive gases are used, it may be desirable to eliminate gas remaining in the gas delivery lines after a deposition. This may be accomplished using a three-way valve, such as valve 143B, to isolate chamber 113 from delivery line 138A and to vent delivery line 138A to vacuum foreline 144, for example. As shown in FIG. 1B, other similar valves, such as 143A and 143C, may be incorporated on other gas delivery lines.

In embodiments, chamber 113 may also has a gas distributor 111 (or top nozzle) and top vent 146. Gas distributor 111 and top vent 146 may allow independent control of top and side flows of the gases, which improves film uniformity and allows fine adjustment of the film's deposition and doping parameters. Top vent 146 may have an annular opening around gas distributor 111. In further embodiments, gas distributor 111 may include a plurality of apertures in a step according to an embodiment of the present invention for improved gas distribution. In still further embodiments, first gas source 134A may supply source gas nozzles 139 and gas distributor 111. In additional embodiments, source nozzle multifunction controller (MFC) 135A′ may control the amount of gas delivered to source gas nozzles 139 and top nozzle MFC 135A controls the amount of gas delivered to gas distributor 111. Similarly, two MFCs 135B and 135B′ may be used to control the flow of oxygen to both top vent 146 and oxidizer gas nozzles 140 from a single source of oxygen, such as source 134B. The gases supplied to gas distributor 111 and top vent 146 may be kept separate prior to flowing the gases into chamber 113, or the gases may be mixed in top plenum 148 before they flow into chamber 113. Separate sources of the same gas may be used to supply various portions of the chamber.

In still more embodiments, a baffle 158 may be formed on gas distributor 111 to direct flows of clean gas toward the chamber wall and can also be used to direct flows of remotely generated plasma and clean gas. The gas distributor may include two separate channels that pass two separate gases into chamber 113 where the gases mix and react above the semiconductor substrate.

In further embodiments, a remote microwave-generated plasma cleaning system 150 may be provided to periodically clean deposition residues from chamber components. The cleaning system includes a remote microwave generator 151 that creates a plasma from a cleaning gas source 134E (e.g., molecular fluorine, nitrogen trifluoride, other fluorocarbons or equivalents) in reactor cavity 153. The reactive species resulting from this plasma are conveyed to chamber 113 through cleaning gas feed port 154 via applicator tube 155. The materials used to contain the cleaning plasma (e.g., cavity 153 and applicator tube 155) are resistant to attack by the plasma. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as electrostatic chuck 120, may not be covered with a dummy wafer or otherwise protected.

In the embodiment shown, the plasma-cleaning system 150 is below the chamber 113, although other positions may alternatively be used, for example above chamber 113. In this alternate embodiment, the distance between the reactor cavity and feed port may be kept short since the concentration of desirable plasma species may decline with distance from reactor cavity. With a cleaning gas feed positioned at the top of the chamber above the baffle, remotely generated plasma species may be provided through the cleaning gas feed port, and can be directed to the sides of the chamber by the baffle.

In embodiments, system controller 160 may control the operation of system 110. In embodiments, controller 160 may include a memory 162, which includes a tangible medium such as a solid-state drive, a hard disk drive, a floppy disk drive (not shown), and/or a card rack (not shown) coupled to a processor 161. The card rack may contain a single-board computer (SBC) (not shown), analog and digital input/output boards (not shown), interface boards (not shown), and stepper motor controller boards (not shown). In embodiments, the system controller may conform to the Versa Modular European (“VME”) standard, which defines board, card cage, and connector dimensions and types. System controller 160 operates under the control of a computer program stored on the tangible medium for example the hard disk drive, or through other computer programs, such as programs stored on a removable disk. The computer program may control, for example, the timing, mixture of gases, RF power levels and other parameters of a particular process. In additional embodiments, the interface between a user and the system controller may be via a touch screen monitor and keyboard.

In embodiments, system controller 160 may control the season time of the chamber and gases used to season the chamber, the clean time and gases used to clean the chamber, and the application of plasma with the HDP CVD process. To achieve this control, the system controller 160 may be coupled to many of the components of system 110. For example, system controller 160 may be coupled to one or more of vacuum system 170, source plasma system 180A, bias plasma system 180B, gas delivery system 133, and remote plasma cleaning system 150. In embodiments, system controller 160 may be coupled to vacuum system 170 with a line 163. In more embodiments, system controller 160 may be coupled to source plasma system 180 with a line 164A and to bias plasma system 180B with a line 164B. In still more embodiments, system controller 160 may be coupled to gas delivery system 133 with a line 165. In yet additional embodiments, system controller 160 may be coupled to remote plasma cleaning system 150 with a line 166. In embodiments, lines 163, 164A, 164B, 165 and 166 may transmit control signals from system controller 160 to vacuum system 170, source plasma system 180A, bias plasma system 180B, gas delivery system 133, and remote plasma cleaning system 150. For example, system controller 160 may separately control each of flow controllers 135A to 135E and 135A′ to 135D′ with line 165. Line 165 may include separate control lines connected to each flow controller. In further embodiments, system controller 160 may include several distributed processors to control the components of system 110.

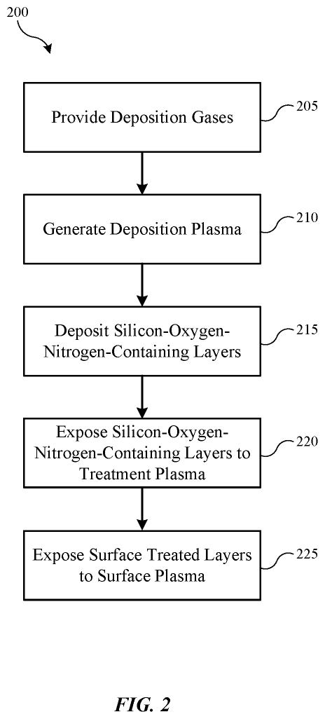

FIG. 2 shows operations of an exemplary method 200 of processing according to some embodiments of the present technology. The method 200 forms a silicon-oxygen-and-nitrogen-containing barrier to prevent moisture and oxygen from contacting a substrate on which the barrier is formed. In some embodiments, the barrier may include a single silicon-oxygen-and-nitrogen-containing layer, while in additional embodiments the barrier may include multiple layers that form a multi-layer stack barrier layer. For both the single layer and multi-layer stack barrier layers, the thickness of the barrier layer is significantly less than a conventional silicon-oxygen-and-nitrogen-containing barrier layer with the same moisture resistance and lower refractive index. In embodiments, the present silicon-oxygen-and-nitrogen-containing barrier layers may be characterized by a thickness of less than or about 3000 Å, less than or about 2900 Å, less than or about 2800 Å, less than or about 2700 Å, less than or about 2600 Å, less than or about 2500 Å, less than or about 2400 Å, less than or about 2300 Å, less than or about 2200 Å, less than or about 2100 Å, less than or about 2000 Å, or less.

In embodiments, the silicon-oxygen-and-nitrogen-containing barrier layer slows or prevents moisture and oxygen on one side of the barrier layer from reaching a substrate in contact with the opposite side of the barrier layer. In further embodiments, the substrate protected from the moisture and oxygen may include moisture and oxygen sensitive materials such as complex light-emitting organic molecules used in OLED displays. In still further embodiments, the barrier layer may cover or encapsulate a pixel, or component of a pixel, in an OLED display.

Method 200 includes providing deposition gases for the deposition of the silicon-oxygen-and-nitrogen-containing material at operation 205. In embodiments, the deposition gases may include one or more silicon-containing gases and one or more nitrogen-containing gases. In still further embodiments, the silicon-containing gases may include silane (SiH₄), among other silicon-containing gases. In further embodiments, the nitrogen-containing gases may include nitrous oxide (N₂O), nitric oxide (NO), nitrogen dioxide (NO₂), and ammonia (NH₃), among other nitrogen-containing gases. In more embodiments, the deposition gases are substantially free of moisture (H₂O) and may be characterized has having a moisture level of less than or about 0.1 wt. %, less than or about 0.01 wt. %, less than or about 0.001 wt. %, or less.

In embodiments, the deposition gases may be provided to a substrate processing region of a substrate processing chamber. In further embodiments, the silicon-containing gases may be provided at a flow rate of greater than or about 10 sccm, greater than or about 20 sccm, greater than or about 30 sccm, greater than or about 40 sccm, greater than or about 50 sccm, greater than or about 60 sccm, greater than or about 70 sccm, greater than or about 80 sccm, greater than or about 90 sccm, greater than or about 100 sccm, or more. In still further embodiments, the nitrogen-containing gases may be provided at a flow rate of greater than or about 10 sccm, greater than or about 25 sccm, greater than or about 50 sccm, greater than or about 75 sccm, greater than or about 100 sccm, greater than or about 125 sccm, greater than or about 150 sccm, greater than or about 175 sccm, greater than or about 200 sccm, or more. In yet more embodiments, the silicon-containing gases to the nitrogen-containing gases may be characterized by a Si-gases-to-N-gases flow rate ratio of less than or about 1:2, less than or about 1:3, less than or about 1:4, less than or about 1:5, less than or about 1:6, less than or about 1:7, less than or about 1:8, less than or about 1:9, less than or about 1:10, or less.

In further embodiments, the nitrogen-containing gases may include two or more nitrogen-containing gases. In still more embodiments, the nitrogen-containing gases may include nitrous oxide (N₂O) and ammonia (NH₃). In yet further embodiments, the NH₃-to-N₂O flow rate ratio may greater than or about 1:1, greater than or about 1.5:1, greater than or about 2:1, greater than or about 2.5:1, greater than or about 3:1, greater than or about 3.5:1, greater than or about 4:1, greater than or about 4.5:1, greater than or about 5:1, or more. In yet more embodiments, the deposition gases may include silane, ammonia, and nitrous oxide, and the SiH₄:NH₃:N₂O flow rate ratio of the gases may be characterized as less than or about 1:4:2. In additional embodiments, the deposition gases may be free of an inert carrier gas such as helium, argon, or molecular nitrogen gas (N₂), among other inert carrier gases. In still additional embodiments, the deposition gases may be free of molecular hydrogen gas (H₂). In yet still additional embodiments, the deposition gases be free of molecular oxygen gas (O₂) or ozone (O₃).

In further embodiments, the deposition gases may be provided to a substrate processing region of a processing chamber. In embodiments, the deposition gases may pressurize processing chamber to a pressure of less than or about 200 mTorr, less than or about 150 mTorr, less than or about 100 mTorr, less than or about 75 mTorr, less than or about 50 mTorr, less than or about 25 mTorr, or less.

Method 200 further includes generating a deposition plasma from the deposition gases at operation 210. In embodiments, the deposition plasma may be characterized as a high-density plasma. In further embodiments, the high-density plasma may be characterized by an ion density greater than or about 1×10¹¹ ions/cm³, greater than or about 2×10¹¹ ions/cm³, greater than or about 3×10¹¹ ions/cm³, greater than or about 4×10¹¹ ions/cm³, greater than or about 5×10¹¹ ions/cm³, greater than or about 6×10¹¹ ions/cm³, greater than or about 7×10¹¹ ions/cm³, greater than or about 8×10¹¹ ions/cm³, greater than or about 9×10¹¹ ions/cm³, greater than or about 1×10¹² ions/cm³, or more. In still further embodiments, the high-density plasma may generate a deposition temperature in the processing chamber that is characterized as less than or about 200° C., less than or about 175° C., less than or about 150° C., less than or about 125° C., less than or about 100° C., or less.

Method 200 also includes depositing one or more silicon-oxygen-and-nitrogen-containing layers on the substrate in the processing chamber at operation 215. In embodiments, the one or more layers may be deposited on an exposed surface of a substrate that is positioned in a substrate processing region of a processing chamber. In additional embodiments, the processing chamber may be an induced-coupled-plasma chemical-vapor-deposition (ICP-CVD) processing chamber like the one shown in FIG. 1B. In further embodiments, the gap between the plasma induction coils and the substrate may be characterized as greater than or about 5000 mils, greater than or about 6000 mils, greater than or about 7000 mils, greater than or about 8000 mils, greater than or about 9000 mils, greater than or about 10,000 mils, greater than or about 11,000 mils, greater than or about 12,500 mils, or more. In further embodiments, the silicon-oxygen-and-nitrogen-containing material may be deposited at a deposition rate of greater than or about 1000 Å/min, greater than or about 1100 Å/min, greater than or about 1200 Å/min, greater than or about 1300 Å/min, greater than or about 1400 Å/min, greater than or about 1500 Å/min, greater than or about 1600 Å/min, greater than or about 1700 Å/min, greater than or about 1800 Å/min, greater than or about 1900 Å/min, greater than or about 2000 Å/min, or more.

In embodiments, the one or more silicon-oxygen-and-nitrogen-containing layers may be deposited as a single layer. In further embodiments, the single-layer silicon-oxygen-and-nitrogen-containing layer may be characterized by a thickness of less than or about 3000 Å, less than or about 2900 Å, less than or about 2800 Å, less than or about 2700 Å, less than or about 2600 Å, less than or about 2500 Å, less than or about 2400 Å, less than or about 2300 Å, less than or about 2200 Å, less than or about 2100 Å, less than or about 2000 Å, or less. In additional embodiment, the one or more silicon-oxygen-and-nitrogen-containing layers may be deposited as a multi-layer stack that includes two or more silicon-oxygen-and-nitrogen-containing layers. In still additional embodiments, each of the silicon-oxygen-and-nitrogen-containing layers in the multi-layer stack may be characterized by a thickness of less than or about 1000 Å, less than or about 900 Å, less than or about 800 Å, less than or about 700 Å, less than or about 600 Å, less than or about 500 Å, less than or about 400 Å, less than or about 300 Å, less than or about 200 Å, less than or about 100 Å, or less. In more embodiments, the multi-layer stack of silicon-oxygen-and-nitrogen-containing layers may include greater than or about two layers, greater than or about three layers, greater than or about four layers, greater than or about five layers, greater than or about six layers, greater than or about seven layers, greater than or about eight layers, greater than or about nine layers, greater than or about ten layers, or more. In still more embodiments, the multi-layer stack of silicon-oxygen-and-nitrogen-containing layers may be characterized by a total thickness of less than or about 3000 Å, less than or about 2900 Å, less than or about 2800 Å, less than or about 2700 Å, less than or about 2600 Å, less than or about 2500 Å, less than or about 2400 Å, less than or about 2300 Å, less than or about 2200 Å, less than or about 2100 Å, less than or about 2000 Å, or less.

In some embodiments, a multi-layer stack may be used instead of a single layer barrier layer of the same thickness to adjust one or more characteristics of the barrier layer such as the type and magnitude of the mechanical stress in the layer, and the index of refractive of the layer, among other barrier layer characteristics. In some embodiments, mechanical stress in the barrier layer may be characterized as a tensile stress of less than or about 200 MPa, less than or about 175 MPa, less than or about 150 MPa, less than or about 125 MPa, less than or about 100 MPa, less than or about 75 MPa, less than or about 50 MPa, less than or about 25 MPa, less than or about 10 MPa, or less. In additional embodiments, the mechanical stress in the barrier layer may be characterized as a compressive stress of greater than or about −200 MPa, greater than or about −175 MPa, greater than or about −150 MPa, greater than or about −125 MPa, greater than or about −100 MPa, greater than or about −75 MPa, greater than or about −50 MPa, greater than or about −25 MPa, greater than or about −10 MPa, or more. In still more embodiments, the barrier layer may be characterized as having neutral stress, with no substantial tensile or compressive stress (i.e., a stress level of about 0 MPa). In further embodiments, the barrier layer may be characterized by a refractive index of less than or about 1.6, less than or about 1.59, less than or about 1.58, less than or about 1.57, less than or about 1.56, less than or about 1.55, less than or about 1.54, less than or about 1.53, less than or about 1.52, less than or about 1.51, less than or about 1.50, or less. In multi-layer stack barrier layers, the mechanical stress and index of refractive may vary between the layers.

In further embodiments, the deposited silicon-oxygen-and-nitrogen-containing layer may be characterized as a high-quality layer. In still further embodiments, the deposited silicon-oxygen-and-nitrogen-containing layer may be characterized by a density of greater than or about 2.0 g/cm³, greater than or about 2.1 g/cm³, greater than or about 2.2 g/cm³, greater than or about 2.3 g/cm³, greater than or about 2.4 g/cm³, greater than or about 2.5 g/cm³, or more. The high density of the deposited silicon-oxygen-and-nitrogen-containing layer contributes to the low wet-etch-rate of the barrier layer. In embodiments, the deposited layer may be characterized by a wet etch rate (WER) of less than or about 2000 Å/min, less than or about 1750 Å/min, less than or about 1500 Å/min, less than or about 1250 Å/min, less than or about 1000 Å/min, less than or about 900 Å/min, less than or about 800 Å/min, less than or about 700 Å/min, less than or about 600 Å/min, less than or about 500 Å/min, less than or about 400 Å/min, less than or about 300 Å/min, less than or about 200 Å/min, less than or about 100 Å/min, or less. The high density and low wet etch rate characteristics of the barrier layer slow the migration of oxygen and moisture through the layer. This permits thinner barrier layers to provide the same level of protection from oxygen and moisture as thicker barrier layers made of less dense material.

In yet further embodiments, the deposited silicon-oxygen-and-nitrogen-containing layer may be characterized as a silicon oxynitride (SiON) layer. In additional embodiments the silicon oxynitride material in the SiON layer may be characterized by the formula SiOₓN_{y}, where x may range from 0.25 to 1.9 and y may range from 0.02 to 1.5. In further embodiments, the as-deposited SiON layer may be characterized by a hydrogen content of less than or about 5 mol. %, less than or about 4 mol. %, less than or about 3 mol. %, less than or about 2 mol. %, less than or about 1 mol. %, or less.

Method 200 further includes exposing the deposited silicon-oxygen-and-nitrogen-containing layers to a treatment plasma at operation 220. In embodiments, the treatment plasma may be formed from at least one nitrogen-containing gas that reacts with hydrophilic groups on the exposed surfaces of the silicon-oxygen-and-nitrogen-containing layers. In additional embodiments, these hydrophilic groups may include ionically charged groups, oxygen-containing groups, and hydroxyl-containing groups on the exposed surfaces of the layers. The reaction of these hydrophilic groups with the nitrogen-containing species in the treatment plasma produces nitrogen-containing groups that are less hydrophilic and a silicon-oxygen-and-nitrogen-containing layer that is more resistant to the transport of oxygen and moisture through the one or more layers.

In embodiments, the exposed surfaces of the silicon-oxygen-and-nitrogen-containing layers treated with the treatment plasma may have more silicon-nitrogen bonds and fewer silicon-oxygen bonds than the surface of the as-deposited layer. In additional embodiments, the treated surfaces may be characterized by an increase in the amount of silicon-nitrogen bonds of greater than or about 10%, greater than or about 20%, greater than or about 30%, greater than or about 40%, greater than or about 50%, or more compared to the untreated surfaces of the as-deposited silicon-oxygen-and-nitrogen-containing layer. In further embodiments, the treated surfaces may be characterized by a decrease in the amount of silicon-oxygen bonds to less than or about 90%, less than or about 80%, less than or about 70%, less than or about 60%, less than or about 50%, or less of the silicon-oxygen bonds on the untreated surfaces of the as-deposited silicon-oxygen-and-nitrogen-containing layer.

In additional embodiments, the treatment plasma may be formed from one or more nitrogen-containing gases such as nitrous oxide (N₂O) and ammonia (NH₃), among other nitrogen-containing gases. In further embodiments, the treatment plasma is silicon free. In still further embodiments, the treatment plasma may be formed by halting the flow of silicon-containing gases in the deposition plasma while the nitrogen-containing gases continue to flow. In embodiments the treatment plasma may be formed from a mixture of N₂O and NH₃ characterized by a N₂O:NH₃ flow rate ratio of less than or about 10:1, less than or about 5:1, less than or about 2:1, less than or about 1:1, or less. In more embodiments, the treatment plasma may be formed from a treatment gas consisting of N₂O. In still more embodiments, the treatment plasma may be formed from a mixture of NH₃ and N₂O characterized by a NH₃:N₂O flow rate ratio of greater than or about 1:1, greater than or about 2:1, greater than or about 5:1, greater than or about 10:1, or more. In additional embodiments, the treatment plasma may be formed from a treatment gas consisting of NH₃. In embodiments, the surfaces of the as-deposited silicon-oxygen-and-nitrogen-containing layers may be exposed to the treatment plasma for less than or about 60 seconds, less than or about 45 seconds, less than or about 30 seconds, less than or about seconds, less than or about 10 seconds, less than or about 5 seconds, less than or about 4 seconds, less than or about 3 seconds, less than or about 2 seconds, less than or about 1 second, or less.

In embodiments, the treated silicon-oxygen-and-nitrogen-containing layers have fewer hydrophilic groups such as ionically charged groups, oxygen groups, and hydroxyl groups, among other hydrophilic groups. The reduced numbers of these hydrophilic groups on the surface of the treated silicon-oxygen-and-nitrogen-containing layers give the layers increased oxygen and moisture resistance. In additional embodiments, a treated 2000 Å silicon-oxygen-and-nitrogen-containing layer may be characterized by a water vapor transmission rate (WVTR) measured at 40° C. in 100% humidity of less than or about 1×10⁻³ g/m² day, less than or about 9×10⁻⁴ g/m² day, less than or about 8×10⁻⁴ g/m² day, less than or about 7×10⁻⁴ g/m² day, less than or about 6×10⁻⁴ g/m² day, less than or about 5×10⁻⁴ g/m² day, less than or about 4×10⁻⁴ g/m² day, less than or about 3×10⁻⁴ g/m² day, less than or about 2×10⁻⁴ g/m² day, less than or about 1×10⁻⁴ g/m² day, or less.

Method 200 may also optionally include exposing the treated silicon-oxygen-and-nitrogen-containing layers to a surface plasma at operation 225. In embodiments, the surface plasma treatment further reduces the free static charges present on the exposed surfaces of the one or more treated layers. The reduced level of static charge on the treated silicon-oxygen-and-nitrogen-containing layers further reduces the hydrophilicity of the layers. In additional embodiments, the surface plasma may be formed from one or more inert gases that do not react with the chemical moieties on the exposed surfaces of the treated silicon-oxygen-and-nitrogen-containing layers. In yet additional embodiments, the inert gases may include molecular nitrogen (N₂), helium (He), and argon (Ar), among other inert gases. In more embodiments, the treated silicon-oxygen-and-nitrogen-containing layers may be exposed to the surface plasma for less than or about 10 seconds, less than or about 7.5 seconds, less than or about 5 seconds, less than or about 2.5 seconds, less than or about 1 second, or less.

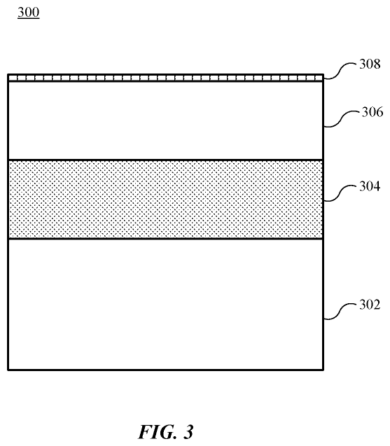

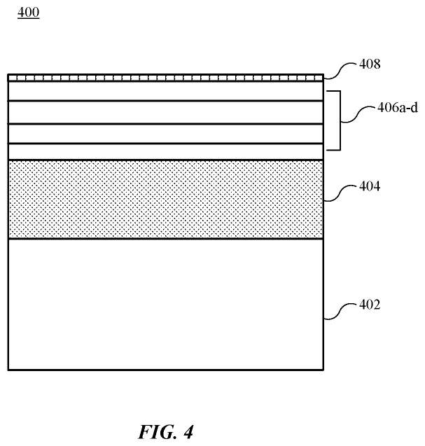

FIGS. 3 and 4 show embodiments of exemplary structures 300 and 400, respectively, according to embodiments of the present technology. The embodiments include a substrate 302, 402, upon which a silicon-oxygen-and-nitrogen-containing barrier layer is formed. In embodiments, the substrate 302, 402, may include silicon-containing materials such as amorphous silicon, polycrystalline silicon, or crystalline silicon, among other silicon-containing materials. In further embodiments, the substrate 302, 402, may include inorganic dielectric materials such as silicon oxide or silicon nitride, among other inorganic dielectric materials. In still further embodiments, the substrate 302, 402, may include organic polymer materials. In more embodiments, the exemplary structures 300 and 400 may include a layer or region of oxygen sensitive material 304, 404, positioned on the substrate 302, 402. In embodiments, the oxygen sensitive material 304, 404, may include complex light-emitting organic molecules used in OLED displays, among other kinds of oxygen-sensitive materials.

In the embodiment shown in FIG. 3, the silicon-oxygen-and-nitrogen-containing barrier layer 306 includes a single layer positioned on the layer of oxygen sensitive material 304. In embodiments, the barrier layer 306 covers or encapsulates the oxygen sensitive material 304 to prevent oxygen and moisture in the region above the barrier layer from contacting the oxygen sensitive material. In further embodiments, the single layer of barrier material 306 may be characterized by a thickness of greater than or about 500 Å and less than or about 2000 Å. In further embodiments, the barrier layer 306 may be characterized by a density of greater than or about 2.0 g/cm³, which contributes to a reduced wet etch rate and reduced water vapor transmission rate through the layer. In embodiments, the barrier layer 306 may be characterized by a wet etch rate of less than or about 3000 Å/minute and a water vapor transmission rate of less than or about 9×10⁻⁴ g/m² day at 40° C. and 100% humidity.

The increased oxygen and moisture resistance of barrier layer 306 may be accompanied by a refractive index that does not interfere with the efficient transmission of light from the oxygen-sensitive light emitting materials in layer 304. This may be accomplished, in part, by the low refractive index of the barrier layer 306. In embodiments, the barrier layer 306 may be characterized by a refractive index of less than or about 1.6.

FIG. 4 shows another embodiment of a barrier layer that includes multiple stacked layers 406a-d of silicon-oxygen-and-nitrogen-containing material. In embodiments, each of the layers 406a-d may independently be less than or about 500 Å, and the total thickness of the layers may sum to less than or about 2000 Å. In further embodiments, the barrier layers 406a-d may be characterized by a density of greater than or about 2.0 g/cm³, a wet etch rate of less than or about 3000 Å/minute. In yet more embodiments, the barrier layers 406a-d may collectively be characterized by a water vapor transmission rate of less than or about 9×10⁻⁴ g/m² day at 40° C. and 100% humidity. In additional embodiments, the barrier layers 406a-d may also be independently characterized by refractive indexes of less than or about 1.6. In still further embodiments, the top barrier layer 406a may have the highest refractive index of all the barrier layers 406a-d.

In embodiments, the exemplary structures 300 and 400 may further include a treated surface 308, 408, that may be a surface of the barrier layer 306, 406a opposite the one in contact with layers 304, 404. In embodiments, the treated surface 308, 408, may be characterized by a higher nitrogen content than the bulk of the barrier layer 306, 406a. In additional embodiments, the treated surface 308, 408, may be characterized by a higher hydrophobicity than the bulk the barrier layer 306, 406a. In still further embodiments, the treated surface 308, 408, may be characterized by a thickness of less than or about 50 nm, less than or about 40 nm, less than or about 30 nm, less than or about 20 nm, less than or about 10 nm, less than or about 5 nm, or less.

Embodiments of the present technology provide oxygen and moisture barrier layers with reduced water vapor transmission rates at reduced barrier thicknesses and reduced refractive indices. This permits the incorporation of thinner barrier layers into electronic products, such as electronic displays, with smaller device dimensions and increased device density. Among other benefits, the shrinking device dimensions made possible by the thinner barrier layers can produce higher resolution, more flexible, and brighter displays. In addition, the increased oxygen and moisture resistance of the present silicon-oxygen-and-nitrogen-containing barrier layers can increase the operational lifetime of the electronics products that incorporate the barrier layers.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a material” includes a plurality of such materials, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A processing method comprising:
flowing deposition gases into a substrate processing region of a processing chamber, wherein the deposition gases include a silicon-containing gas and a nitrogen-containing gas;
generating a deposition plasma from the deposition gases in the substrate processing region;
depositing a silicon-oxygen-and-nitrogen-containing layer on a substrate from the deposition plasma; and
exposing a surface of the silicon-oxygen-and-nitrogen-containing layer to a treatment plasma to form a treated silicon-oxygen-and-nitrogen-containing layer having a treated surface with an increased amount of silicon-nitrogen bonds and a decreased amount of silicon-oxygen bonds, wherein the treatment plasma is formed from a nitrogen-containing gas and is silicon free.

2. The processing method of claim 1, wherein the silicon-oxygen-and-nitrogen-containing layer is characterized by thickness of less than or about 2000 Å.

3. The processing method of claim 1 wherein the silicon-containing gas comprises silane and the nitrogen-containing gas comprises nitrous oxide.

4. The processing method of claim 1, wherein the deposition gases further comprise ammonia.

5. The processing method of claim 1, wherein the deposition plasma is characterized by an ion density of greater than or about 1×10¹¹ ions/cm³, and wherein the silicon-oxygen-and-nitrogen-containing layer deposited on the substrate is characterized by a deposition temperature of less than or about 100° C.

6. The processing method of claim 1, wherein the treated silicon-oxygen-and-nitrogen-containing layer is characterized by a wet etch rate of less than or about 3000 Å/min.

7. The processing method of claim 1, wherein the treated silicon-oxygen-and-nitrogen-containing layer is characterized by a density of greater than or about 2.1 g/cm³.

8. The processing method of claim 1, wherein the treated silicon-oxygen-and-nitrogen-containing layer is characterized by an index of refraction of less than or about 1.6.

9. A processing method comprising:
depositing a first silicon-oxygen-and-nitrogen-containing layer on a substrate, wherein the first silicon-oxygen-and-nitrogen-containing layer is characterized by a thickness of less than or about 500 Å;
depositing at least one additional silicon-oxygen-and-nitrogen-containing layer on the first silicon-oxygen-and-nitrogen-containing layer to form a multi-layer stack of silicon-oxygen-and-nitrogen-containing layers, wherein the multi-layer stack is characterized by a thickness of less than or about 2000 Å; and
exposing a top surface of the multi-layer stack to a treatment plasma to form a treated multi-layer stack, wherein the treatment plasma is formed from a nitrogen-containing gas and is silicon free.

10. The processing method of claim 9, wherein the first silicon-oxygen-and-nitrogen-containing layer and the at least one additional silicon-oxygen-and-nitrogen-containing layer are deposited with a deposition plasma characterized by an ion density of greater than or about 1×10¹¹ ions/cm³.

11. The processing method of claim 10, wherein the deposition plasma is generated from deposition gases comprising a silicon-containing gas and a nitrogen-containing gas.

12. The processing method of claim 9, wherein the treated multi-layer stack is characterized by an index of refraction of less than or about 1.6.

13. The processing method of claim 9, wherein the treated multi-layer stack is characterized by a wet etch rate of less than or about 3000 Å/min.

14. The processing method of claim 9, wherein the nitrogen-containing gas in the treatment plasma comprises ammonia.

15. A structure comprising:
a substrate; and
at least one silicon-oxygen-and-nitrogen-containing layer positioned on the substrate, wherein the at least one silicon-oxygen-and-nitrogen-containing layer is characterized by a thickness of less than or about 2000 Å, a refractive index of less than or about 1.6, and a wet etch rate of less than or about 3000 Å/min.

16. The structure of claim 15, wherein the at least one silicon-oxygen-and-nitrogen-containing layer is a single silicon-oxygen-and-nitrogen-containing layer.

17. The structure of claim 15, wherein the at least one silicon-oxygen-and-nitrogen-containing layer comprises at least two layers of silicon-oxygen-and-nitrogen-containing material, and wherein each of the at least two layers is characterized by a thickness of less than or about 500 Å.

18. The structure of claim 17, wherein the at least two layers of silicon-oxygen-and-nitrogen-containing material comprises a top layer characterized by a stress level that is different than other layers of the silicon-oxygen-and-nitrogen-containing materials.

19. The structure of claim 15, wherein the at least one silicon-oxygen-and-nitrogen-containing layer is characterized by a density of greater than or about 2.1 g/cm³.

20. The structure of claim 15, wherein the at least one silicon-oxygen-and-nitrogen-containing layer comprises silicon oxynitride.
